(19) United States
(12) Patent Application Publication
(10) Pub. No.: US 2025/0105158 A1
(43) Pub. Date: Mar. 27, 2025

(54) SEMICONDUCTOR PACKAGE

(71) Applicant: SAMSUNG ELECTRONICS CO., LTD., Suwon-si (KR)

(72) Inventors: Sung Min MOON, Suwon-si (KR); Pyoung Wan KIM, Suwon-si (KR)

(21) Appl. No.: 18/735,789

(22) Filed: Jun. 6, 2024

(30) Foreign Application Priority Data
Sep. 25, 2023 (KR) 10-2023-0127870

(51) Int. Cl. H01L 23/538; H01L 23/00; H01L 23/36; H01L 23/498; H01L 25/00; H10B 80/00

(52) U.S. Cl. CPC H01L 23/5385; H01L 23/36; H01L 25/00; H10B 80/00; H01L 23/49816; H01L 24/16; H01L 24/17; H01L 2224/16225; H01L 2224/17181

(57) ABSTRACT

A semiconductor package includes: a substrate including a first surface extended in first and second directions that cross each other; a semiconductor chip disposed on the substrate; a first memory chip structure disposed on the substrate, and including a plurality of first memory chips that are stacked on each other in a third direction that is substantially perpendicular to the first and second directions; a first interposer disposed on the semiconductor chip and the first memory chip structure; a second memory chip structure disposed on the first interposer, and including a plurality of second memory chips that are stacked on each other in the third direction; and a heat dissipation structure disposed on the semiconductor chip, wherein a length of the heat dissipation structure is smaller than a length of the semiconductor chip based on the first direction.

### CROSS-REFERENCE TO RELATED APPLICATION

This application claims priority under 35 USC § 119 to Korean Patent Application No. 10-2023-0127870 filed on Sep. 25, 2023 in the Korean Intellectual Property Office, the disclosure of which is incorporated by reference herein in its entirety.

### TECHNICAL FIELD

Embodiments of the present inventive concept relate to a semiconductor package.

### DISCUSSION OF THE RELATED ART

With the development of the electronic industry, electronic devices are gradually becoming smaller and more multifunctional, and accordingly, a desire for an increase in the capacity and speed of a memory used in electronic devices is also increasing. Accordingly, various technologies have been under development to increase the capacity of the memory and increase a driving speed of the memory while decreasing the size of the semiconductor package.

In this respect, a system-in-package technology, in which semiconductor memory devices are integrated into one package structure to allow one semiconductor package product to perform high-speed operation, large-capacity data processing, and multifunctional operation, is desirable. In addition, a High Bandwidth Memory (HBM) technology, which implements a large-capacity memory by vertically stacking multiple semiconductor chips by using a through silicon via (TSV) technology, is currently under development.

### SUMMARY

According to example embodiments of the present inventive concept, a semiconductor package includes: a substrate including a first surface extended in first and second directions that cross each other; a semiconductor chip disposed on the substrate; a first memory chip structure disposed on the substrate, and including a plurality of first memory chips that are stacked on each other in a third direction that is substantially perpendicular to the first and second directions; a first interposer disposed on the semiconductor chip and the first memory chip structure; a second memory chip structure disposed on the first interposer, and including a plurality of second memory chips that are stacked on each other in the third direction; and a heat dissipation structure disposed on the semiconductor chip, wherein a length of the heat dissipation structure is smaller than a length of the semiconductor chip based on the first direction.

According to example embodiments of the present inventive concept, a semiconductor package includes: a first interposer; a processor disposed on the first interposer; a first memory chip structure including a plurality of first memory chips that are spaced apart from the processor in a horizontal direction on the first interposer and are stacked on each other in a vertical direction; a second interposer disposed on the processor and the first memory chip structure; a second memory chip structure disposed on the second interposer, and including a plurality of second memory chips that are stacked on each other in the vertical direction; and a heat dissipation structure disposed on the processor, wherein a first electrical path that electrically connects the processor with the first memory chip structure and a second electrical path that electrically connects the processor with the second memory chip structure are independent of each other.

According to example embodiments of the present inventive concept, a semiconductor package includes: a first interposer; a processor disposed on the first interposer; a first memory chip structure including a plurality of first memory chips that are spaced apart from the processor on the first interposer and are stacked on each other in a vertical direction; a second interposer disposed on the processor and the first memory chip structure; a second memory chip structure disposed on the second interposer, and including a plurality of second memory chips that are stacked on each other in the vertical direction; and a dummy silicon chip disposed on the processor, wherein the processor includes a first region, in which the dummy silicon chip is formed, and a second region, in which the dummy silicon chip is not formed, and the second interposer is disposed in the second region without being disposed in the first region.

### BRIEF DESCRIPTION OF THE DRAWINGS

The above and features of the present inventive concept will become more apparent by describing in detail example embodiments thereof with reference to the attached drawings, in which:

FIG. 1 is a plan view illustrating a semiconductor package according to example embodiments of the present inventive concept;

FIG. 2 is a cross-sectional view taken along line A-A of FIG. 1;

FIGS. 3, 4, 5, 6 and 7 are cross-sectional views illustrating a semiconductor package according to example embodiments of the present inventive concept;

FIG. 8 is a plan view illustrating a semiconductor package according to example embodiments of the present inventive concept; and

FIGS. 9, 10 and 11 are views illustrating intermediate steps of a method of manufacturing a semiconductor package according to example embodiments of the present inventive concept.

### DETAILED DESCRIPTION OF THE EMBODIMENTS

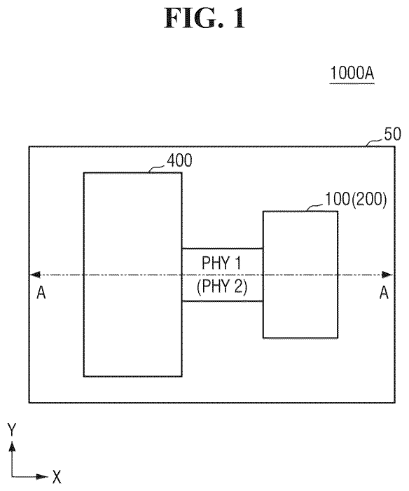

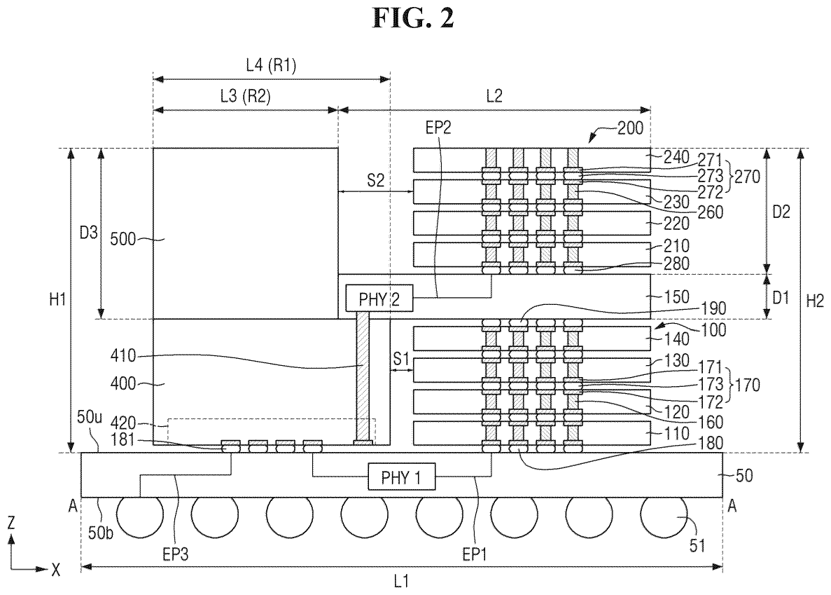

Hereinafter, a semiconductor package according to example embodiments of the present inventive concept will be described with reference to FIGS. 1 and 2.

FIG. 1 is a plan view illustrating a semiconductor package according to example embodiments of the present inventive concept. FIG. 2 is a cross-sectional view taken along line A-A of FIG. 1.

Referring to FIGS. 1 and 2, a semiconductor package 1000A according to example embodiments of the present inventive concept includes a first substrate 50, a semiconductor chip 400, a first memory chip structure 100, a second substrate 150, a second memory chip structure 200 and a first heat dissipation structure 500.

In example embodiments of the present inventive concept, the first substrate 50 may be referred to as a first interposer. For example, the first substrate 50 may include at least one of silicon, glass, ceramic or plastic, but the present inventive concept is not limited thereto.

For another example, the first substrate 50 may be a printed circuit board (PCB) or a ceramic substrate, but the present inventive concept is not limited thereto.

When the first substrate 50 is a printed circuit board, the first substrate 50 may include at least one of, for example, a phenolic resin, an epoxy resin or polyimide. For example, the first substrate 50 may include at least one of FR4, tetrafunctional epoxy, polyphenylene ether, epoxy/polyphenylene oxide, bismaleimide triazine (BT), thermount, cyanate ester, polyimide or liquid crystal polymer. A surface of the first substrate 50 may be covered by a solder resist, but the present inventive concept is not limited thereto.

The first substrate 50 may include a lower surface 50b and an upper surface 50u, which are opposite to each other. The lower surface 50b and the upper surface 50u of the first substrate 50 may be extended in a first direction X and a second direction Y, respectively.

In example embodiments of the present inventive concept, each of the first direction X and the second direction Y may be a direction that is parallel with the upper surface 50u of the first substrate 50 and may cross each other. A third direction Z is a direction perpendicular to each of the first direction X and the second direction Y, and may refer to a direction in which first and second memory chip structures 100 and 200, which will be described later, are stacked. Each of the first direction X and the second direction Y may be referred to as a horizontal direction, and the third direction Z may be referred to as a vertical direction.

A connection terminal 51 may be disposed on the lower surface 50b of the first substrate 50. The connection terminal 51 may be a solder bump or a solder ball. The connection terminal 51 may be connected to a first electrical path EP1, which receives a data signal from the outside of the first substrate 50, and a power signal path EP3, which receives a power signal.

The connection terminal 51 may include at least one of, for example, tin (Sn), indium (In), lead (Pb), zinc (Zn), nickel (Ni), gold (Au), silver (Ag), copper (Cu), antimony (Sb), bismuth (Bi) or a combination thereof, but the present inventive concept is not limited thereto.

The semiconductor chip 400 may be disposed on the first substrate 50. The semiconductor chip 400 may be packaged through (1_1)th lower solder bumps 181 that are disposed on the upper surface 50u of the first substrate 50. The semiconductor chip 400 may be a micro-processor. The semiconductor chip 400 may be, for example, a central processing unit (CPU), a controller or an application specific integrated circuit (ASIC). In example embodiments of the present inventive concept, the semiconductor chip 400 may be referred to as a processor.

The semiconductor chip 400 may be connected to a power signal path EP3, which is formed inside the first substrate 50, through a portion of the (1_1)th lower solder bumps 181. The semiconductor chip 400 may be connected to the first electrical path EP1, which is formed inside the first substrate 50, through another portion of the (1_1)th lower solder bumps 181.

The semiconductor chip 400 may include a first region R2 in which the first heat dissipation structure 500, which will be described later, is formed, and a second region (region of R1 except R2) in which the first heat dissipation structure 500 is not formed. In this case, the second substrate 150 might not be disposed in the first region R2 but may be disposed in the second region (region R1 except R2).

The semiconductor chip 400 may include a through via 410 that extended into the semiconductor chip 400 and a wiring layer 420 that is inside the semiconductor chip 400. The through via 410 may be extended in the third direction Z to at least partially pass through the semiconductor chip 400. The wiring layer 420 may include a plurality of conductive pads.

The second substrate 150 may be electrically connected to the wiring layer 420, which is inside the semiconductor chip 400, through the through via 410. The through via 410 might not be disposed in the first region R2.

The through via 410 may include at least one of, for example, aluminum (Al), gold (Au), beryllium (Be), bismuth (Bi), cobalt (Co), copper (Cu), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), tellurium (Te), titanium (Ti), tungsten (W), zinc (Zn) or zirconium (Zr), but the present inventive concept is not limited thereto.

The first memory chip structure 100 may be spaced apart from the semiconductor chip 400 in the first direction X on the first substrate 50. The first memory chip structure 100 may include a plurality of first memory chips 110, 120, 130 and 140, a first through via 160, a first connection structure 170, a (1_2)th lower solder bump 180 and a first upper solder bump 190. The first connection structure 170 may include pads 171 and 172 and a first solder bump 173 between the plurality of first memory chips 110, 120, 130 and 140.

The first memory chip structure 100 may be packaged on the first substrate 50 through the (1_2)th lower solder bump 180. The first memory chip structure 100 may be a high bandwidth memory (HBM). The first memory chip structure 100 may include a plurality of first memory chips 110, 120, 130 and 140 that are vertically stacked on each other. For example, each of the plurality of first memory chips 110, 120, 130 and 140 may be a volatile memory semiconductor chip such as a Dynamic Random Access Memory (DRAM) or a Static Random Access Memory (SRAM), or may be a nonvolatile memory semiconductor chip such as a Phase Change Random Access Memory (PRAM), a Magnetoresistive Random Access Memory (MRAM), a Ferroelectric Random Access Memory (FeRAM) or a Resistive Random Access Memory (RRAM), but the present inventive concept is not limited thereto.

For example, the plurality of first memory chips 110, 120, 130 and 140 may be homogeneous memory chips. For another example, at least some of the plurality of first memory chips 110, 120, 130 and 140 may be heterogeneous memory chips.

The first through via 160 and the first and second pads 171 and 172 may be formed in each of the plurality of first memory chips 110, 120, 130 and 140. The first through via 160 may be formed by passing through each of the first memory chips 110, 120, 130 and 140. The first and second pads 171 and 172 may be electrically connected to a lower portion and an upper portion of the first through via 160, respectively.

The first and second pads 171 and 172 may be exposed at the surfaces of the first memory chips 110, 120, 130 and 140. The first solder bump 173 may be disposed between the plurality of first memory chips 110, 120, 130 and 140. The first solder bump 173 may be in contact with the first and second pads 171 and 172. The respective first memory chips 110, 120, 130 and 140 may be electrically connected to each other through the first through via 160, the first and second pads 171 and 172 and the first solder bump 173.

The first memory chip structure 100 may include two, four, eight or twelve memory chips, but the present inventive concept are not limited thereto. In example embodiments of the present inventive concept, the first memory chip structure 100 may include a plurality of first memory chips 110, 120, 130 and 140 that are sequentially stacked on each other. The first memory chip 110 of the first memory chip structure 100 may be positioned at a lowermost position of the first memory chip structure 100 on the first substrate 50, and the fourth memory chip 140 of the first memory chip structure 100 may be positioned on an uppermost position of the first memory chip structure 100 on the first substrate 50.

For example, the first memory chip 110 of the first memory chip structure 100 may be a buffer chip. In this case, the first memory chip 110 of the first memory chip structure 100 may be a controller for providing signals to the other memory chips 120, 130 and 140.

The second substrate 150 may be disposed on the semiconductor chip 400 and the first memory chip structure 100. The first upper solder bump 190 may be disposed between the second substrate 150 and the first memory chip structure 100. In example embodiments of the present inventive concept, the second substrate 150 may be referred to as a second interposer.

The second substrate 150 may be extended on the upper surface of the semiconductor chip 400 to cover a portion of the upper surface of the semiconductor chip 400. For example, the second substrate 150 may cover only a portion of the upper surface of the semiconductor chip 400. A length L2 in which the second substrate 150 is extended in the first direction X may be smaller than a length L1 in which the first substrate 50 is extended in the first direction X.

For example, the second substrate 150 may include at least one of silicon, glass, ceramic or plastic, but the present inventive concept is not limited thereto.

The second memory chip structure 200 may be disposed on the second substrate 150. The second memory chip structure 200 may be spaced apart from the first heat dissipation structure 500, which will be described later, in the first direction X on the second substrate 150. The second memory chip structure 200 may include a plurality of second memory chips 210, 220, 230, 240, a second through via 260, a second connection structure 270, a second lower solder bump 280 and a second upper solder bump. The second connection structure 270 may include pads 271 and 272 and a second solder bump 273 that is disposed between the plurality of second memory chips 210, 220, 230 and 240.

That is, a portion of the second substrate 150 may be disposed between the second memory chip structure 200 and the first memory chip structure 100. The second memory chip structure 200 may be packaged on the second substrate 150 through the second lower solder bump 280. The second memory chip structure 200 may be disposed to overlap the first memory chip structure 100 in the third direction Z. The second memory chip structure 200 might not overlap the semiconductor chip 400 in the third direction Z.

The second memory chip structure 200 may be a high bandwidth memory (HBM). The second memory chip structure 200 may include a plurality of second memory chips 210, 220, 230 and 240 that are vertically stacked on each other. For example, each of the plurality of first memory chips 210, 220, 230 and 240 may be a volatile memory semiconductor chip such as a Dynamic Random Access Memory (DRAM) or a Static Random Access Memory (SRAM), or may be a nonvolatile memory semiconductor chip such as a Phase Change Random Access Memory (PRAM), a Magnetoresistive Random Access Memory (MRAM), a Ferroelectric Random Access Memory (FeRAM) or a Resistive Random Access Memory (RRAM), but the present inventive concept is not limited thereto.

For example, all of the plurality of second memory chips 210, 220, 230 and 240 may be homogeneous memory chips. For another example, at least some of the plurality of second memory chips 210, 220, 230 and 240 may be heterogeneous memory chips.

The second through via 260 and the third and fourth pads 271 and 272 may be formed in each of the plurality of second memory chips 210, 220, 230 and 240. The second through via 260 may penetrate each of the second memory chips 210, 220, 230 and 240. The third and fourth pads 271 and 272 may be electrically connected to a lower portion and an upper portion of the second through via 260, respectively.

The third and fourth pads 271 and 272 may be exposed at surfaces of the second memory chips 210, 220, 230 and 240. The second solder bump 273 may be disposed between the plurality of second memory chips 210, 220, 230 and 240. The second solder bump 273 may be in contact with the third and fourth pads 271 and 272. The respective second memory chips 210, 220, 230 and 240 may be electrically connected to each other through the second through via 260, the third and fourth pads 271 and 272 and the second solder bump 273.

The second memory chip structure 200 may include two, four, eight or twelve memory chips, but the present inventive concept is not limited thereto. In example embodiments of the present inventive concept, the second memory chip structure 200 may include a plurality of second memory chips 210, 220, 230 and 240 that are sequentially stacked on each other. The first memory chip 210 of the second memory chip structure 200 may be positioned at a lowermost position of the second memory chip structure 200 on the second substrate 150, and the fourth memory chip 240 of the second memory chip structure 200 may be positioned at an uppermost position of the second memory chip structure on the second substrate 150.

For example, the fourth memory chip 240 of the second memory chip structure 200 may be a buffer chip. In this case, the fourth memory chip 240 of the second memory chip structure 200 may be a controller for providing signals to the other memory chips 210, 220, 230.

The first substrate 50 may include a first physical layer (PHY) PHY 1 for transmitting and receiving an electrical signal between the semiconductor chip 400 and the first memory chip structure 100. The first PHY PHY 1 may be a physical layer for transmitting and receiving an electrical signal between the semiconductor chip 400 and the first memory chip structure 100. The first electrical path EP1 for electrically connecting the semiconductor chip 400 with the first memory chip structure 100 to each other may be formed in the first substrate 50.

The second substrate 150 may include a second PHY PHY 2 for transmitting and receiving an electrical signal between the semiconductor chip 400 and the second memory chip structure 200. The second PHY PHY 2 may be a physical layer for transmitting and receiving an electrical signal between the semiconductor chip 400 and the second memory chip structure 200. The second electrical path EP2 for electrically connecting the semiconductor chip 400 with the second memory chip structure 200 may be formed in the second substrate 150.

The first PHY PHY 1 and the second PHY PHY 2 may at least partially overlap each other in the third direction Z, but the present inventive concept is not limited thereto.

The first PHY PHY 1 and the second PHY PHY 2 might not be electrically connected to each other. In addition, the first electrical path EP1 and the second electrical path EP2 might not be connected to each other. The second electrical path EP2 may be electrically connected to the through via 410, but the first electrical path EP1 might not be electrically connected to the through via 410. In other words, the first PHY PHY 1 and the second PHY PHY 2 may form their respective electrical paths that are independent of each other.

Therefore, the first memory chip structure 100 and the second memory chip structure 200 might not be electrically connected to each other. The first memory chip structure 100 and the second memory chip structure 200 may be electrically independent of each other. For example, the first memory chip structure 100 may be insulated from the second memory chip structure 200. For example, the first electrical path EP1, which is for electrically connecting the semiconductor chip 400 with the first memory chip structure 100, and the second electrical path EP2, which is for electrically connecting the semiconductor chip 400 with the second memory chip structure 200, may be independent of each other.

The first heat dissipation structure 500 may be disposed on the semiconductor chip 400. An uppermost surface of the first heat dissipation structure 500 may be substantially coplanar with an uppermost surface of the second memory chip structure 200. In this case, based on the third direction Z, a height H1 from the upper surface 50u of the first substrate 50 to the uppermost surface of the first heat dissipation structure 500 may be substantially the same as a height H2 from the upper surface 50u of the first substrate 50 to the uppermost surface of the second memory chip structure 200.

The first heat dissipation structure 500 may be in contact with the upper surface of the semiconductor chip 400 without being disposed on the second substrate 150. The first heat dissipation structure 500 might not be disposed on the first memory chip structure 100 and the second memory chip structure 200.

A length L3 of the upper surface of the first heat dissipation structure 500 may be smaller than a length L4 of the upper surface of the semiconductor chip 400 based on the first direction X. A thickness D3 of the first heat dissipation structure 500 may be substantially the same as the sum of a thickness D1 of the second substrate 150 and a thickness D2 of the second memory chip structure 200 based on the third direction Z.

A spaced distance S1 that is between the semiconductor chip 400 and the first memory chip structure 100 may be smaller than a spaced distance S2 that is between the first heat dissipation structure 500 and the second memory chip structure 200 based on the first direction X. For example, based on the first direction X, the spaced distance S1 that is between the semiconductor chip 400 and at least one memory chip of the first memory chip structure 100 may be smaller than the spaced distance S2 that is between the first heat dissipation structure 500 and at least one memory chip of the second memory chip structure 200.

The first heat dissipation structure 500 may include silicon (Si). The first heat dissipation structure 500 might not be electrically connected to the semiconductor chip 400. In example embodiments of the present inventive concept, the first heat dissipation structure 500 may be referred to as a dummy silicon chip.

A mold layer may be disposed on the first substrate 50. The mold layer may integrally cover the first memory chip structure 100, the second memory chip structure 200, the semiconductor chip 400 and the first heat dissipation structure 500. The mold layer may cover at least a portion of an upper surface and a lower surface of the second substrate 150. The mold layer may include, for example, an epoxy molding compound (EMC) or two or more silicon hybrid materials.

According to example embodiments of the present inventive concept, an electrical path between the processor 400 and the lower memory chip structure 100 and an electrical path between the processor 400 and the upper memory chip structure 200 may be separated from each other. Therefore, the density of wires for transmitting and receiving data within the same area of the interposers 50 and 150 may be increased, and at the same time, signal interference between the wires may be minimized. In addition, the heat dissipation structure 500 may be disposed in the semiconductor package, so that a heat dissipation phenomenon that may be generated in the process of transmitting and receiving data may be reduced.

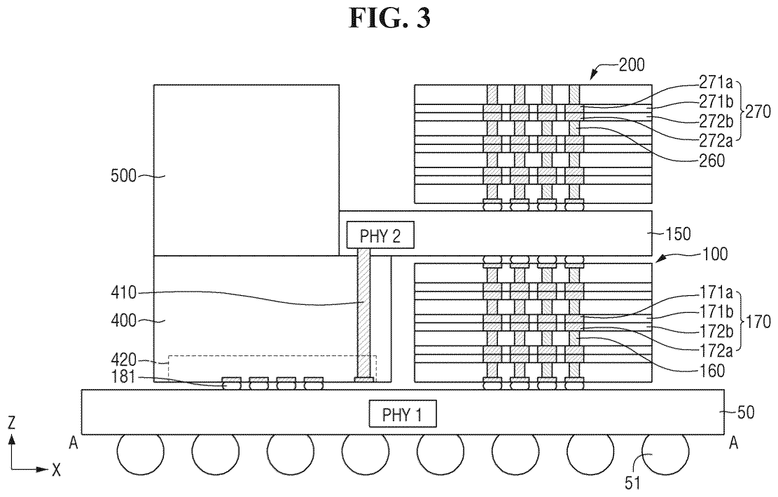

Hereinafter, the semiconductor package according to example embodiments of the present inventive concept will be described with reference to FIGS. 3 to 7. The following descriptions will be based on differences from the semiconductor packages shown in FIGS. 1 and 2. In addition, redundant descriptions may be omitted or briefly discussed.

FIGS. 3 to 7 are cross-sectional views illustrating a semiconductor package according to example embodiments of the present inventive concept. For reference, FIGS. 3 to 7 are cross-sectional views corresponding to FIG. 2.

Referring to FIG. 3, the first memory chip structure 100 may include a first connection structure 170 for bonding the plurality of first memory chips 110, 120, 130 and 140 to each other. The first connection structure 170 may include first bonding pads 171a and 172a and first bonding insulating layers 171b and 172b between the plurality of first memory chips 110, 120, 130 and 140. The first bonding pads 171a and 172a and the first bonding insulating layers 171b and 172b may bond upper and lower memory chips 110, 120, 130 and 140 to each other. For example, the first bonding pads 171a and 172a may include a conductive material such as copper (Cu), and the first bonding insulating layers 171b and 172b may include an insulating material.

The second memory chip structure 200 may include a second connection structure 270 for bonding the plurality of second memory chips 210, 220, 230 and 240 to each other. The second connection structure 270 may include second bonding pads 271a and 272a and second bonding insulating layers 271b and 272b between the plurality of second memory chips 210, 220, 230 and 240. The second bonding pads 271a and 272a and the second bonding insulating layers 271b and 272b may bond the upper and lower memory chips 210, 220 and 230 and 240 to each other. For example, the second bonding pads 271a and 272a may include a conductive material such as copper (Cu), and the second bonding insulating layers 271b and 272b may include an insulating material.

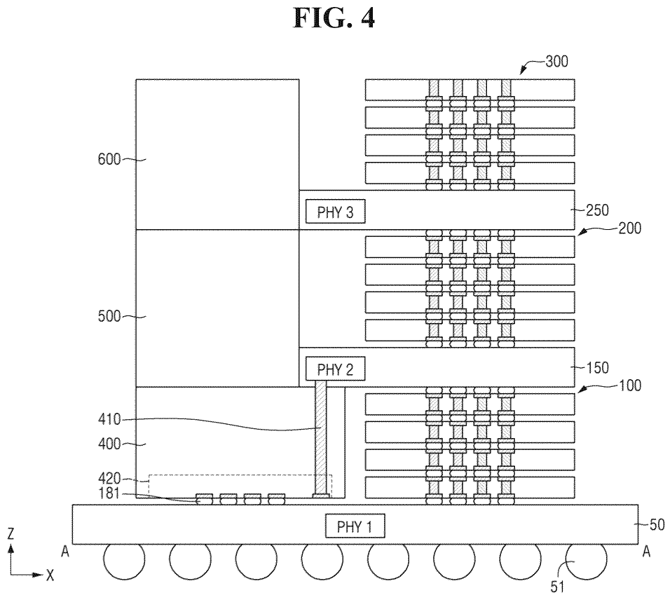

Referring to FIG. 4, the semiconductor package according to example embodiments of the present inventive concept may further include a third substrate 250, a third memory chip structure 300 and a second heat dissipation structure 600.

The third substrate 250 may be disposed on the second memory chip structure 200. The third substrate 250 may be disposed on a portion of the semiconductor chip 400.

In example embodiments of the present inventive concept, the third substrate 250 may be referred to as a third interposer. In example embodiments of the present inventive concept, the description of the second substrate 150 may be equally applied to the third substrate 250.

The third memory chip structure 300 may be disposed on the second memory chip structure 200. The third memory chip structure 300 may include a plurality of third memory chips stacked on each other in the third direction Z. The third memory chip structure 300 may include two, four, eight or twelve memory chips, but the present inventive concept is not limited thereto.

The third substrate 250 may include a third PHY PHY 3 for transmitting and receiving an electrical signal between the semiconductor chip 400 and the third memory chip structure 300. The first PHY PHY 1 and the third PHY PHY 3 might not be electrically connected to each other, and the second PHY PHY 2 and the third PHY PHY 3 might not be electrically connected to each other.

The second heat dissipation structure 600 may be disposed on the first heat dissipation structure 500. For example, the second heat dissipation structure 600 may be directly disposed on the first heat dissipation structure 500. The second heat dissipation structure 600 might not be disposed on the third substrate 250. In example embodiments of the present inventive concept, the description of the first heat dissipation structure 500 may be equally applied to the second heat dissipation structure 600.

Additional substrates and additional memory chip structures may be stacked on the third memory chip structure 300. In this case, additional heat dissipation structures may be stacked on the second heat dissipation structure 600.

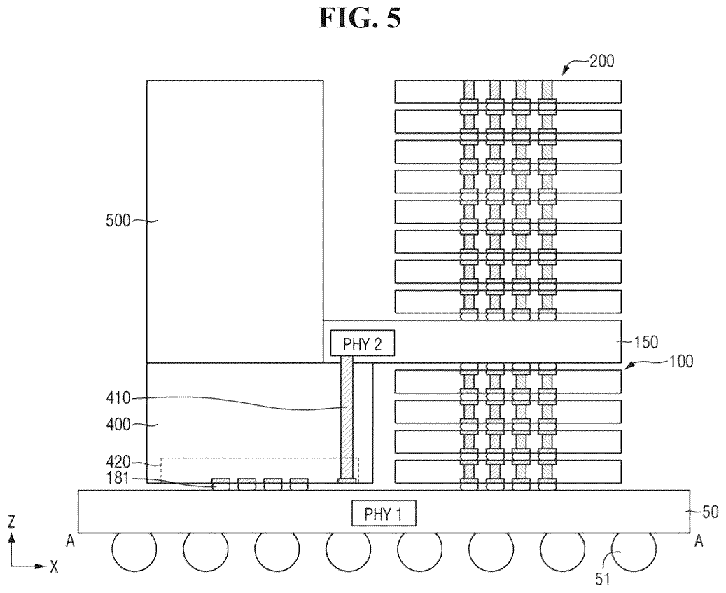

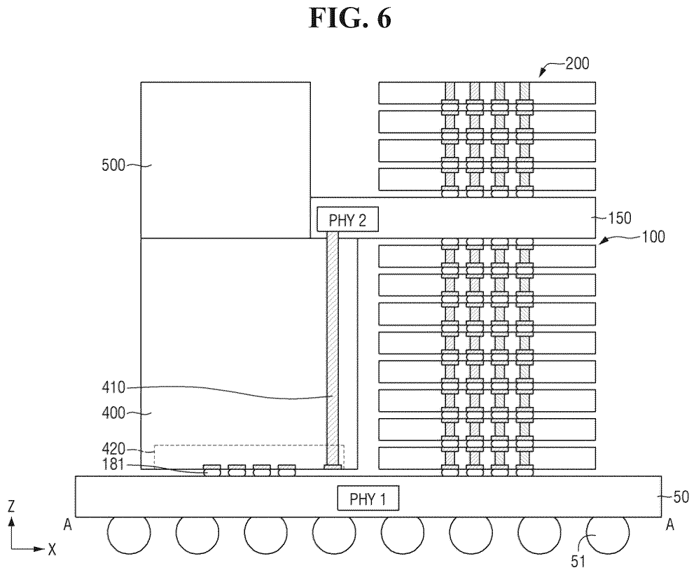

Referring to FIGS. 5 and 6, the number of the plurality of first memory chips that are included in the first memory chip structure 100 may be different from the number of the plurality of second memory chips that are included in the second memory chip structure 200.

For example, as shown in FIG. 5, the number of the plurality of first memory chips that are included in the first memory chip structure 100 may be smaller than the number of the plurality of second memory chips that are included in the second memory chip structure 200. For example, the first memory chip structure 100 may include four memory chips and the second memory chip structure 200 may include eight memory chips, but the present inventive concept is not limited thereto. For another example, the first memory chip structure 100 may include eight memory chips, and the second memory chip structure 200 may include twelve memory chips.

In addition, for example, as shown in FIG. 6, the number of the plurality of first memory chips that are included in the first memory chip structure 100 may be greater than the number of the plurality of second memory chips that are included in the second memory chip structure 200. For example, the first memory chip structure 100 may include eight memory chips and the second memory chip structure 200 may include four memory chips, but the present inventive concept not limited thereto. For another example, the first memory chip structure 100 may include twelve memory chips, and the second memory chip structure 200 may include eight memory chips.

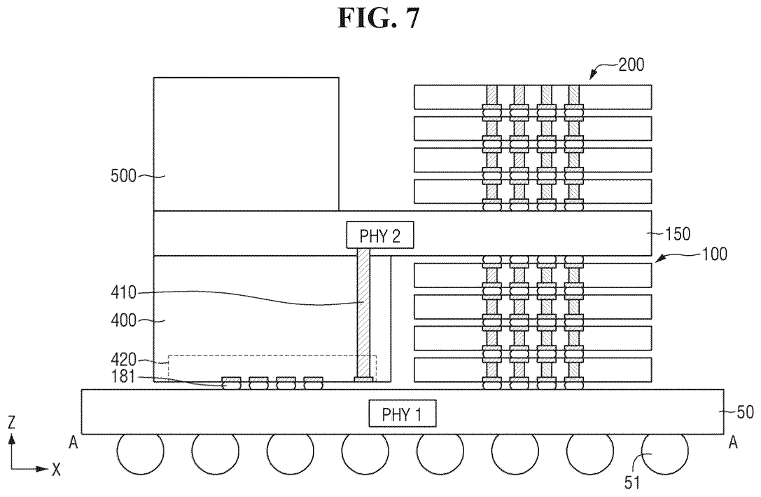

Referring to FIG. 7, the second substrate 150 may be extended on the semiconductor chip 400 to cover the entire upper surface of the semiconductor chip 400. For example, the second substrate 150 may contact the entire upper surface of the semiconductor chip 400. In this case, the second substrate 150 may be interposed between the semiconductor chip 400 and the first heat dissipation structure 500.

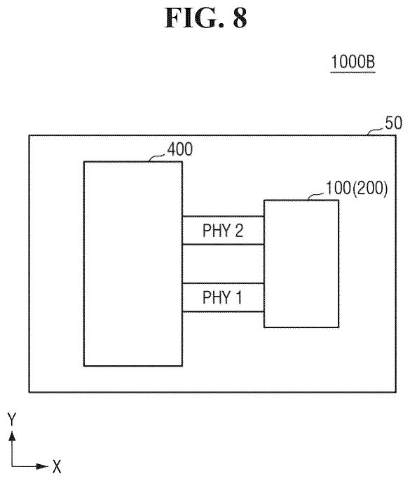

Hereinafter, the semiconductor package according to example embodiments of the present inventive concept will be described with reference to FIG. 8. The following description will be based on differences from the semiconductor package shown in FIGS. 1 to 7. In addition, redundant descriptions may be omitted or briefly discussed.

FIG. 8 is a plan view illustrating a semiconductor package according to example embodiments of the present inventive concept. For reference, FIG. 8 is a plan view corresponding to FIG. 1.

Referring to FIG. 8, in a semiconductor package 1000B according to example embodiments of the present inventive concept, the first PHY PHY 1 and the second PHY PHY 2 may be spaced apart from each other based on the second direction Y. For example, the first PHY PHY 1 and the second PHY PHY 2 might not overlap each other based on the third direction Z.

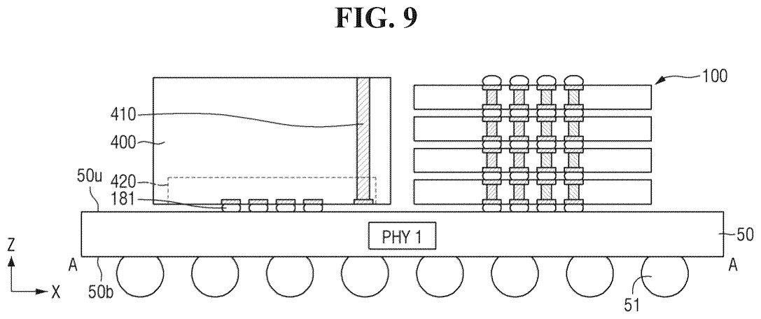

Hereinafter, a method for fabricating a semiconductor package according to example embodiments of the present inventive concept will be described with reference to FIGS. 9 to 11. The following description will be based on differences from the semiconductor package shown in FIGS. 1 and 2. In addition, redundant descriptions may be omitted or briefly discussed.

FIGS. 9 to 11 are views illustrating intermediate steps of a method of manufacturing a semiconductor package according to example embodiments of the present inventive concept. For reference, FIGS. 9 to 11 are views illustrating intermediate steps of a method of manufacturing the semiconductor package shown in FIG. 2.

Referring to FIG. 9, the first memory chip structure 100 and the semiconductor chip 400 may be formed on the upper surface 50u of the first substrate 50. The connection terminal 51 may be formed on the lower surface 50b of the first substrate 50. The semiconductor chip 400 may be packaged through the first lower solder bump 181 being disposed on the upper surface 50u of the first substrate 50.

The first memory chip structure 100 and the semiconductor chip 400 may be spaced apart from each other in the first direction X. The through via 410 and the wiring layer 420, which are extended into the semiconductor chip 400, may be formed in the semiconductor chip 400.

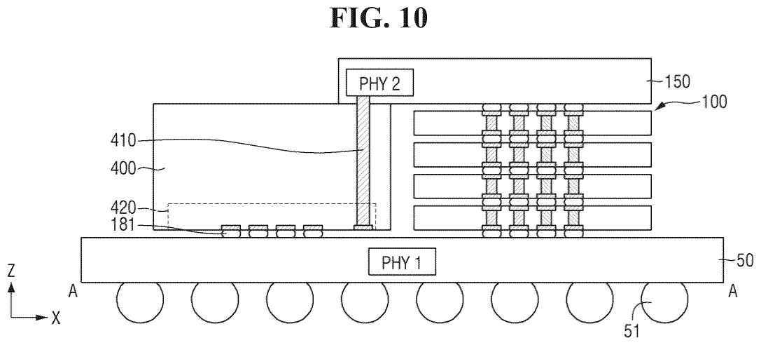

Referring to FIG. 10, the second substrate 150 may be formed on the first memory chip structure 100. The second substrate 150 may be extended on the upper surface of the semiconductor chip 400 to cover only a portion of the upper surface of the semiconductor chip 400.

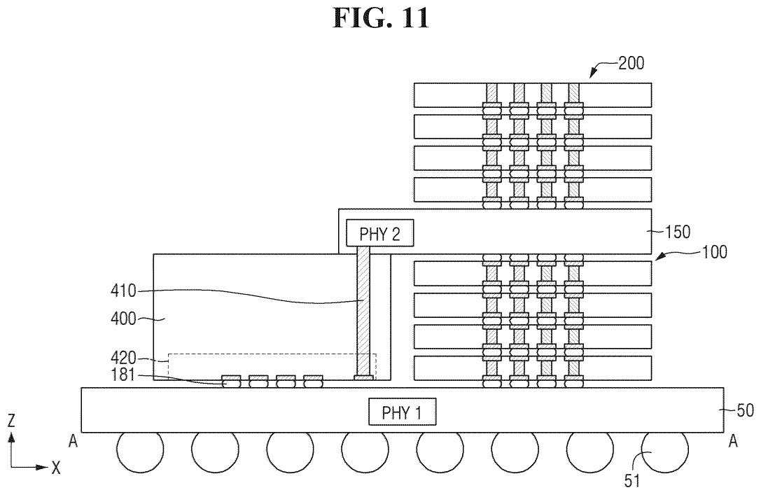

Referring to FIG. 11, the second memory chip structure 200 may be formed on the second substrate 150. The second PHY PHY 2 may be electrically connected to the through via 410, and the first PHY PHY 1 might not be electrically connected to the through via 410.

An electrical signal may be transmitted and received between the semiconductor chip 400 and the first memory chip structure 100 through the first PHY PHY 1 in the first substrate 50. An electrical signal may be transmitted and received between the semiconductor chip 400 and the second memory chip structure 200 through the second PHY PHY 2 in the second substrate 150.

The first PHY PHY 1 and the second PHY PHY 2 may form their respective electrical paths that are independent of each other. Therefore, the first memory chip structure 100 and the second memory chip structure 200 might not be electrically connected to each other.

Afterwards, the first heat dissipation structure 500 may be formed on the semiconductor chip 400. Therefore, the semiconductor package such as that shown in FIG. 2 may be formed.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor package comprising:
a substrate including a first surface extended in first and second directions that cross each other;
a semiconductor chip disposed on the substrate;
a first memory chip structure disposed on the substrate, and including a plurality of first memory chips that are stacked on each other in a third direction that is substantially perpendicular to the first and second directions;
a first interposer disposed on the semiconductor chip and the first memory chip structure;
a second memory chip structure disposed on the first interposer, and including a plurality of second memory chips that are stacked on each other in the third direction; and
a heat dissipation structure disposed on the semiconductor chip,
wherein a length of the heat dissipation structure is smaller than a length of the semiconductor chip based on the first direction.

2. The semiconductor package of claim 1, wherein the substrate includes a first physical layer (PHY) that transmits and receives an electrical signal between the semiconductor chip and the first memory chip structure,
the first interposer includes a second PHY that transmits and receives an electrical signal between the semiconductor chip and the second memory chip structure, and
the first PHY and the second PHY are not electrically connected to each other.

3. The semiconductor package of claim 1, wherein the first memory chip structure and the second memory chip structure are not electrically connected to each other.

4. The semiconductor package of claim 1, wherein a first surface of the heat dissipation structure is substantially coplanar with a first surface of the second memory chip structure.

5. The semiconductor package of claim 4, wherein a height from the first surface of the substrate to the first surface of the heat dissipation structure is substantially the same as a height from the first surface of the substrate to the first surface of the second memory chip structure.

6. The semiconductor package of claim 1, wherein a length of the first interposer is smaller than a length of the substrate based on the first direction.

7. The semiconductor package of claim 1, wherein the first interposer is electrically connected to a wiring layer that is inside the semiconductor chip through a through via that is extended into the semiconductor chip.

8. The semiconductor package of claim 1, wherein a spaced distance that is between the first memory chip structure and the semiconductor chip is smaller than a spaced that is distance between the second memory chip structure and the heat dissipation structure based on the first direction.

9. The semiconductor package of claim 1, further comprising:
a second interposer disposed on the second memory chip structure; and
a third memory chip structure disposed on the second memory chip structure, and including a plurality of third memory chips that are stacked on each other in the third direction,
wherein the second interposer includes a third PHY that transmits and receives an electrical signal between the semiconductor chip and the third memory chip structure.

10. The semiconductor package of claim 1, wherein a number of the first memory chips that are included in the first memory chip structure is different from a number of the second memory chips that are included in the second memory chip structure.

11. A semiconductor package comprising:
a first interposer;
a processor disposed on the first interposer;
a first memory chip structure including a plurality of first memory chips that are spaced apart from the processor in a horizontal direction on the first interposer and are stacked on each other in a vertical direction;
a second interposer disposed on the processor and the first memory chip structure;
a second memory chip structure disposed on the second interposer, and including a plurality of second memory chips that are stacked on each other in the vertical direction; and
a heat dissipation structure disposed on the processor,
wherein a first electrical path that electrically connects the processor with the first memory chip structure and a second electrical path that electrically connects the processor with the second memory chip structure are independent of each other.

12. The semiconductor package of claim 11, wherein a thickness of the heat dissipation structure is substantially the same as a sum of a thickness of the second interposer and a thickness of the second memory chip structure based on the vertical direction.

13. The semiconductor package of claim 11, wherein the heat dissipation structure includes silicon (Si).

14. The semiconductor package of claim 11, wherein the first interposer includes a first PHY that transmits and receives an electrical signal between the processor and the first memory chip structure,
the second interposer includes a second PHY that transmits and receives an electrical signal between the processor and the second memory chip structure, and
the first PHY and the second PHY are not electrically connected to each other.

15. The semiconductor package of claim 14, wherein the first PHY and the second PHY at least partially overlap each other based on the vertical direction.

16. The semiconductor package of claim 14, wherein the first PHY and the second PHY are spaced apart from each other based on the horizontal direction.

17. The semiconductor package of claim 14, further comprising:
a third interposer disposed on the second memory chip structure; and
a third memory chip structure disposed on the second memory chip structure, and including a plurality of third memory chips that are stacked on each other in the vertical direction,
wherein the third interposer includes a third PHY that transmits and receives an electrical signal between the processor and the third memory chip structure.

18. The semiconductor package of claim 17, wherein the first PHY and the third PHY are not electrically connected to each other, and the second PHY and the third PHY are not electrically connected to each other.

19. A semiconductor package comprising:
a first interposer;
a processor disposed on the first interposer;
a first memory chip structure including a plurality of first memory chips that are spaced apart from the processor on the first interposer and are stacked on each other in a vertical direction;
a second interposer disposed on the processor and the first memory chip structure;
a second memory chip structure disposed on the second interposer, and including a plurality of second memory chips that are stacked on each other in the vertical direction; and
a dummy silicon chip disposed on the processor,
wherein the processor includes a first region, in which the dummy silicon chip is formed, and a second region, in which the dummy silicon chip is not formed, and
the second interposer is disposed in the second region without being disposed in the first region.

20. The semiconductor package of claim 19, wherein a first electrical path that electrically connects the processor with the first memory chip structure is formed in the first interposer,
a second electrical path that electrically connects the processor with the second memory chip structure through a through via that is extended into the processor is formed in the second interposer, and
the first electrical path and the second electrical path are not connected to each other.
